(19) United States
(12) Patent Application Publication
(10) Pub. No.: US 2022/0336771 A1
(43) Pub. Date: Oct. 20, 2022

(54) ORGANIC LIGHT EMITTING DIODE DISPLAY DEVICE AND MANUFACTURING METHOD THEREOF

(71) Applicant: DB HiTek Co., Ltd., Bucheon-si (KR)

(72) Inventor: Young Jin KIM, SeouI (KR)

(21) Appl. No.: 17/719,882

(22) Filed: Apr. 13, 2022

(30) Foreign Application Priority Data
Apr. 16, 2021 (KR) 10-2021-0049523

(51) Int. Cl. H01L 51/52; H01L 51/56

(52) U.S. Cl. CPC H01L 51/5209; H01L 51/56

(57) ABSTRACT

An organic light-emitting diode display device and a manufacturing method thereof are disclosed. More particularly, an organic light-emitting diode display device, including a reflective metal having an at least partially non-flat upper surface, may realize a high-luminance micro-display with improved reflectivity, while preventing the reflective metal from being damaged during subsequent processing.

### CROSS REFERENCE TO RELATED APPLICATION(S)

The present application claims priority to Korean Patent Application No. 10-2021-0049523, filed Apr. 16, 2021, the entire contents of which are incorporated herein for all purposes by this reference.

### BACKGROUND OF THE INVENTION

### 1. Technical Field

The present disclosure relates generally to an organic light-emitting diode display device and a manufacturing method thereof. More particularly, the present disclosure relates to an organic light-emitting diode display device, including a reflective metal having an at least partially non-flat upper surface, thereby realizing a high-luminance micro-display with improved reflectivity, while preventing the reflective metal from being damaged during subsequent processing.

### 2. Description of the Related Art

As society has entered the Information Age, the field of display devices that represent electrical signals as visual images has grown rapidly. Thus, a variety of flat display devices, exhibiting excellent performance in view of thinness, light weight, and low power consumption have been developed. Specific examples of the flat panel display devices may include a liquid crystal display (LCD) device, a plasma display panel (PDP) device, a field emission display (FED) device, an organic light-emitting diode (OLED) display device, etc.

In particular, the organic light-emitting diode display device is a self-emissive device. Compared to other flat panel display devices, the organic light-emitting diode display device has the advantages of a fast response time, a high luminous efficiency, a high luminance, and a wide viewing angle. Also, the organic light-emitting diode display device can be implemented with a high resolution and a wide screen and thus is attracting attention as a next-generation display device. An organic light-emitting diode display device has a structure including an organic emitting layer between two electrodes (an anode and a cathode).

Electrons and holes are injected into the organic emitting layer from the two electrodes, and they recombine to form an exciton. The exciton transitions from an excited state to a ground state, leading to emission of light. The organic light-emitting diode display device employs such a principle.

FIG. 1 is a cross-sectional view illustrating an anode metal region in a conventional organic light-emitting diode display device 9.

Referring to FIG. 1, the anode metal region of the conventional organic light-emitting diode display device 9 has a structure including a reflective lower electrode 910 having a flat upper surface, a dielectric layer 930 on an upper surface of the reflective electrode 910, and an anode 950 on the dielectric layer 930. As described above, since the upper surface of the reflective electrode 910 is substantially flat, part of the light reflected by the reflective electrode 910 is reflected again by an overlying interface, and does not pass through the uppermost surface of the device. In other words, there is a problem of lowering luminous efficiency.

Referring to FIG. 1, in the structure of the conventional organic light-emitting diode display device 9, the anode 950 covers only an upper surface of the dielectric layer 930. Therefore, lateral sides of the reflective electrode 910 under the dielectric layer 930 may be externally exposed during subsequent processing. Here, when a subsequent ashing process or heat treatment process is performed with the lateral sides of the reflective electrode 910 exposed, the reflective electrode 910 may be damaged because it is made of silver and/or aluminum, and may thus have a low melting point. Such damage may cause a decrease in reflectivity of the reflective electrode 910 and may result in a leakage path between adjacent pixel regions R, G, and B.

In order to prevent such problems, the inventors of the present disclosure have created a novel organic light-emitting diode display device and a manufacturing method thereof that realize a high-luminance micro-display with improved reflectivity and that prevent a reflective metal from being damaged during subsequent processing.

The foregoing is intended merely to aid in the understanding of the background of the present disclosure, and is not intended to mean that the present disclosure falls within the purview of the related art that is already known to those skilled in the art.

Documents of Related Art

(Patent document 1) Korean Patent Application Publication No. 10-2015-0038982 “Organic Light Emitting Display Device”

### SUMMARY OF THE INVENTION

Accordingly, the present disclosure has been made keeping in mind the above problems occurring in the related art, and an objective of the present disclosure is to provide an organic light-emitting diode display device and a manufacturing method thereof, in which a reflective metal in each pixel region has an upper surface with at least two arbitrary points of different heights, thereby increasing the possibility of lowering the angle of incidence of light striking the reflective metal to be less than or equal to a critical angle. This facilitates efficient extraction of light that is reflected repeatedly and that may be lost in a conventional structure to thereby increase luminous efficiency.

Another objective of the present disclosure is to provide an organic light-emitting diode display device and a manufacturing method thereof, in which a dielectric layer and/or anode metal cover(s) an entire exposed surface of a reflective metal made of or comprising silver or aluminum, in order to prevent the reflective metal from being damaged or exposed during subsequent etching and heat treatment processes, the reflective metal, thereby preventing a decrease in reflectivity and/or luminous efficiency.

Another objective of the present disclosure is to provide an organic light-emitting diode display device and a manufacturing method thereof that block a lateral leakage current path between adjacent pixel regions by preventing defects in a reflective metal, thereby increasing the current applied to the organic light-emitting diode display device and thus increasing the overall efficiency.

Another objective of the present disclosure is to provide an organic light-emitting diode display device and a manufacturing method thereof, including an anode metal having a third extended portion connected to a lower end of a second extended portion on an upper insulating film, thereby preventing external exposure of a reflective metal as much as possible.

Another objective of the present disclosure is to provide an organic light-emitting diode display device and a manufacturing method thereof, in which the third extended portion of the anode metal and a trench and/or hole in an upper insulating film can be simultaneously formed, thereby eliminating any need for a separate process to form the third extended portion of the anode metal and thus facilitating the manufacturing process.

In order to achieve the above objectives, the present disclosure may be implemented by one or more of the following exemplary embodiments.

According to one or more embodiments of the present disclosure, there is provided an organic light-emitting diode display device including a substrate; a lower insulating film on the substrate; a lower metal on the lower insulating film; an upper insulating film on the lower insulating film and surrounding the lower metal; and a lower electrode structure on the upper insulating film. Here, the lower electrode structure may include a reflective metal configured to reflect light incident on the upper insulating film, and the reflective metal may have a non-flat portion in each pixel region (e.g., of the display device).

According to one or more other embodiments of the present disclosure, the reflective metal may have a portion having tangential angles at two arbitrary points in each pixel region that are different from each other.

According to one or more other embodiments of the present disclosure, the reflective metal may have at least two arbitrary points of different heights in each pixel region.

According to one or more other embodiments of the present disclosure, the lower electrode structure may further include: a dielectric layer on the reflective metal; and an anode metal on the dielectric layer.

According to one or more other embodiments of the present disclosure, the upper insulating film may have a non-flat portion in each pixel region, and the reflective metal may have (i) a lower surface on the non-flat portion of the upper insulating film and (ii) a shape conforming to the non-flat portion of the upper insulating film.

According to one or more other embodiments of the present disclosure, there is provided an organic light-emitting diode display device including: a substrate; a lower insulating film on the substrate; a lower metal on the lower insulating film; an upper insulating film on the lower insulating film and surrounding the lower metal; and a lower electrode structure on the upper insulating film. Here, the lower electrode structure may include a reflective metal configured to reflect light incident on the upper insulating film; and an anode metal on the reflective metal. The reflective metal may have a non-flat portion in each pixel region, and the anode metal may cover lateral walls of the reflective metal.

According to one or more other embodiments of the present disclosure, the lower electrode structure may further include a dielectric layer between the reflective metal and the anode metal, the dielectric layer may cover lateral walls of the reflective metal, and the anode metal may entirely cover side walls of the dielectric layer.

According to one or more other embodiments of the present disclosure, the anode metal may have a shape conforming to that of the reflective metal.

According to one or more other embodiments of the present disclosure, the lower electrode structure may further include a buffer metal between the upper insulating film and the reflective metal.

According to one or more other embodiments of the present disclosure, each of the upper insulating film and the buffer metal may have a non-flat portion in each pixel region.

According to one or more other embodiments of the present disclosure, the upper insulating film may include a trench and/or hole at a boundary between adjacent pixel regions.

According to one or more other embodiments of the present disclosure, there is provided a method of manufacturing an organic light-emitting diode display device, the method including forming a lower insulating film on a substrate; forming a lower metal on the lower insulating film; forming an upper insulating film on the lower metal and the lower insulating film; and forming a lower electrode structure on the upper insulating film. Here, forming the lower electrode structure may include forming a reflective metal on the lower insulating film so as to have at least two points of different heights in each pixel region (e.g., of the display device).

According to one or more other embodiments of the present disclosure, forming the upper insulating film may include depositing the upper insulating film on the lower insulating film; and forming a non-flat portion (e.g., in the upper insulating film) by partially etching an upper surface of the upper insulating film in each pixel region.

According to one or more other embodiments of the present disclosure, the reflective metal may be formed on the upper insulating film in each pixel region, and the reflective metal may have a substantially uniform thickness.

According to one or more other embodiments of the present disclosure, forming the lower electrode structure may further include forming a dielectric layer on the reflective metal; and forming an anode metal on the dielectric layer. The dielectric layer may entirely cover exposed sides of the reflective metal.

According to one or more other embodiments of the present disclosure, forming the lower electrode structure may further include forming an anode metal on the reflective metal, the anode metal having a shape corresponding to the reflective metal.

According to one or more other embodiments of the present disclosure, there is provided a method of manufacturing an organic light-emitting diode display device, the method including forming a lower insulating film on a substrate; forming a lower metal on the lower insulating film; forming an upper insulating film on the lower metal and the lower insulating film; and forming a lower electrode structure on the upper insulating film. Here, forming the lower electrode structure may include forming a reflective metal on the lower insulating film so as to have at least two points of different heights in each pixel region; forming a dielectric layer on the reflective metal; and forming an anode metal on the reflective metal. The anode metal may entirely cover exposed sides of the dielectric layer and the reflective metal.

According to one or more other embodiments of the present disclosure, forming the lower electrode structure may further include forming a buffer metal on the upper insulating film, before forming the reflective metal.

The present disclosure has the following effects by the above configurations.

A reflective metal in each pixel region has an upper surface with at least two arbitrary points of different heights. This configuration increases the possibility of lowering the angle of incidence of light striking the reflective metal to be less than or equal to a critical angle. Therefore, there is an effect of facilitating efficient extraction of light that is reflected repeatedly and that may be lost in a conventional structure to thereby increase luminous efficiency.

Furthermore, after formation of a reflective metal made of or comprising silver or aluminum, in order to prevent the reflective metal from being damaged or exposed during subsequent etching and heat treatment processes, a dielectric layer and/or an anode metal covers the entire exposed surface of the reflective metal. Therefore, there is an effect of preventing a decrease in reflectivity and luminous efficiency.

Furthermore, a lateral leakage current path between adjacent pixel regions is blocked by preventing defects in the reflective metal. Therefore, there is an effect of increasing the current to the organic light-emitting diode display device and thus increasing the overall efficiency.

Furthermore, the anode metal may include a third extended portion connected to a lower end of a second extended portion on an upper insulating film. Therefore, there may be an effect of preventing external exposure of the reflective metal as much as possible.

Furthermore, during patterning for forming the third extended portion of an anode metal, a trench and/or hole can be simultaneously formed with the third extended portion in an upper insulating film. Therefore, any need for separate processing (e.g., to form one or more of the extended portions) may be eliminated, thus facilitating the manufacturing process.

Meanwhile, the effects of the present disclosure are not limited to the above-mentioned effects, and other effects not mentioned above can be clearly understood from the following description by a person of ordinary skill in the art.

### BRIEF DESCRIPTION OF THE DRAWINGS

The above and other objectives, features, and other advantages of the present disclosure will be more clearly understood from the following detailed description when taken in conjunction with the accompanying drawings, in which:

FIG. 1 is a cross-sectional view illustrating an anode metal region in a conventional organic light-emitting diode display device;

FIG. 2 is a cross-sectional view illustrating an organic light-emitting diode display device according to one or more embodiments of the present disclosure;

FIG. 3 is a cross-sectional view illustrating the improvement in reflectivity by the reflective metal structure in the organic light-emitting diode display device according to the present disclosure;

FIG. 4 is a cross-sectional view illustrating an organic light-emitting diode display device according to another embodiment of the present disclosure; and

FIGS. 5 to 13 are reference views illustrating a method of manufacturing an organic light-emitting diode display device according to one or more embodiments of the present disclosure.

### DETAILED DESCRIPTION OF THE INVENTION

Reference will now be made in detail to exemplary embodiments of the disclosure, examples of which are illustrated in the accompanying drawings. Embodiments of the present disclosure can be modified in various forms. Therefore, the scope of the disclosure should not be construed as being limited to the following embodiments, but should be construed on the basis of the descriptions in the appended claims. Additionally, the embodiments described hereinbelow are merely representative for purposes of allowing those skilled in the art to more clearly comprehend the present disclosure.

As used herein, the singular forms are intended to include the plural forms as well, unless the context clearly indicates otherwise. It will be further understood that the terms “comprise” and/or “comprising”, etc. when used in this specification, specify the presence of stated features, integers, steps, operations, elements, components, and/or combinations thereof but do not preclude the presence or addition of one or more other features, integers, steps, operations, elements, components, and/or combinations thereof.

As used herein, when an element (or layer) is referred to as being on another element (or layer), it can be directly on the other element, or one or more intervening elements (or layers) may be therebetween. In contrast, when an element is referred to as being directly on or above another component, intervening element(s) are not located therebetween. Note that the terms “on”, “above”, “below”, “upper”, “lower”, etc., are intended to describe one element's relationship to one or more other elements as illustrated in the figures.

When a certain embodiment may be implemented differently, a specific process order may be performed differently from the described order. For example, two consecutively described processes may be performed substantially at the same time or performed in an order opposite to the described order, unless the corresponding context indicates otherwise.

FIG. 2 is a cross-sectional view illustrating an organic light-emitting diode display device 1 according to one or more embodiments of the present disclosure.

Hereinafter, the organic light-emitting diode display device 1 according to the present disclosure will be described in detail with reference to the accompanying drawings.

Referring to FIG. 2, the organic light-emitting diode display device 1 according to the present disclosure is an organic light-emitting diode display device, including a reflective metal in each of a plurality of pixel regions R, G, and B, having an at least partially non-flat or non-planar upper surface, thereby realizing a high-luminance micro-display with improved reflectivity, while preventing the reflective metal from being damaged during subsequent processing.

The organic light-emitting diode display device 1 according to the present disclosure may include organic light-emitting diodes on silicon (OLEDoS), which is a result of forming organic light-emitting diodes on a silicon wafer substrate, but there are no limitations thereto. The OLEDoS may have a structure including an organic light-emitting diode on an electrode formed by, for example, a CMOS process.

A description will be given of the structure of the organic light-emitting diode display device 1 according to the present disclosure. A driving element (not shown) may be on the substrate 101. For example, a source metal, a drain metal, etc. may be on the substrate 101. In addition, a lower insulating film 110 may be on the substrate 101. The lower insulating film 110 insulates the source metal, the drain metal, etc. from the structures thereabove, and may be or comprise, for example, a silicon oxide film, a silicon nitride film, or a multilayer film thereof, but there are no limitations thereto (e.g., other than the lower insulating film 110 comprising electrically insulating material[s]).

An upper insulating film 120 and a lower metal 130 may be on the lower insulating film 110, and the upper insulating film 120 may cover the lower metal 130. The upper insulating film 120 may also be or comprise, for example, a silicon oxide film, a silicon nitride film, or a multilayer film thereof. In addition, for example, the lower metal 130 may be on an upper surface of the lower insulating film 110 in each of the pixel regions R, G, and B.

In addition, the upper insulating film 120 may have an upper surface with one or more non-flat or non-planar portions. For example, in each of the pixel regions R, G, and B, the upper insulating film 120 may have the non-flat portion 120a. Furthermore, the cross-section of the non-flat portion 120a may be triangular, but there are no limitations thereto. In other words, it is sufficient that the upper insulating film 120 has a portion in which the upper surface height is not constant between at least two arbitrary points in each of the pixel regions R, G, and B. Alternatively, the upper insulating film 120 may have a substantially flat upper surface.

One or more contact holes 121 may be in the upper insulating film 120 to provide a contact 140 therein, connecting a lower electrode structure 150 to the lower metal 130. The contact holes 121 extend through the upper insulating film 120 to an upper portion (e.g., an uppermost surface) of the lower metal 130. As illustrated, a pair of contact holes 121 may be spaced apart from each other in each of the pixel regions R, G, and B, but there are no limitations thereto. The lower metal 130 and the contact 140 may be made of or comprise a conductive metal so as to be electrically connected to each other. In addition, it is preferable that a trench and/or hole 123 is in the upper insulating film 120 at the boundary between each of the pixel regions R, G, and B to prevent leakage current from occurring between the pixels.

The lower electrode structure 150 may be on the upper insulating film 120 in each of the pixel regions R, G, and B. The lower electrode structure 150 may include a buffer metal 151, a reflective metal 153, a dielectric layer 155, and an anode metal 157 in sequence (e.g., from lowest to highest). Here, it should be noted that the dielectric layer 155 is not an essential element of the present disclosure.

The buffer metal 151 is on the upper insulating film 120 and under the reflective metal 153, and may be made of or comprise titanium nitride (TiN) or a multilayer structure of titanium nitride (TiN) and titanium (Ti), but it should be noted that the buffer metal 151 is not an essential element of the present disclosure. In addition, when the upper insulating film 120 has the non-flat portion 120a, the buffer metal 151 may be on the non-flat portion 120a in a shape conforming to the non-flat portion 120a. In other words, the buffer metal 151 may also include an extended portion 151a extending upwards along a lateral direction.

In this case, the extended portion 151a may extend at a substantially constant inclination angle, or may extend so that tangential angles at two arbitrary points are different from each other. In other words, the shape of the extended portion 151a is not limited, and it is sufficient that the extended portion 151a has different heights at least two arbitrary points along the lateral direction in each of the pixel regions R, G, and B. Alternatively, the buffer metal 151 may have a substantially flat upper surface.

The reflective metal 153 may be made of or comprise silver (Ag), having a high reflectivity for light in red and green wavelength ranges, and/or aluminum (Al), having a high reflectivity to light in a blue wavelength range, but there are no limitations thereto. In more detail, it is preferable that the reflective metal 153 made of or comprising silver (Ag) having a high reflectivity for light in the red and green wavelength ranges is in each of the red pixel region R and the green pixel region G, and the reflective metal 153 made of or comprising aluminum (Al) having a high reflectivity for light in the blue wavelength range is in the blue pixel region B.

The reflective metal 153 may also include an extended portion 153a extending upwards along the lateral direction in each of the pixel regions R, G, and B. For example, the reflective metal 153 may have at least two arbitrary points of different heights in each of the pixel regions R, G, and B. In some embodiments, when the display device is horizontal as shown in FIG. 2, the extended portion 153a may have a lowermost surface at one or more points or locations that is at a height above the uppermost surface of the non-extended portion of the reflective metal 153. In this case, the cross-section of the reflective metal 153 may be triangular as illustrated or may be curved, but there are no limitations thereto.

Hereinafter, a description will be given of the structure and problems of a conventional organic light-emitting diode display device 9 and the structure of the organic light-emitting diode display device 1 according to the present disclosure for solving the conventional problems.

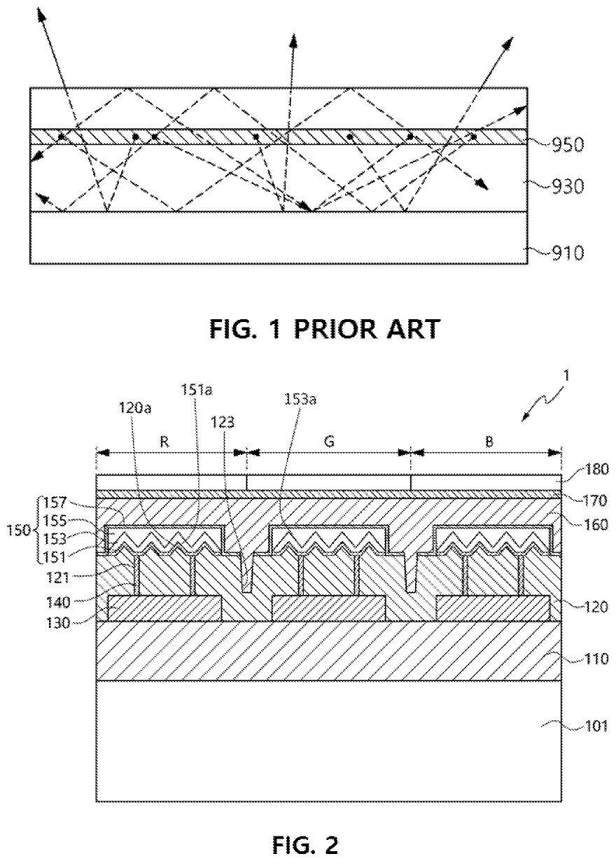

Referring to FIG. 1, the conventional organic light-emitting diode display device 9 has a structure including a reflective lower electrode 910 having a flat upper surface, and a dielectric layer 930 on an upper surface of the reflective electrode 910, and an anode 950 on the dielectric layer 930. As described above, since the upper surface of the reflective electrode 910 is substantially flat, a part of the light reflected by the reflective electrode 910 is reflected again by an overlying interface and does not pass through the uppermost surface of the device. In other words, there is a problem of luminous inefficiency.

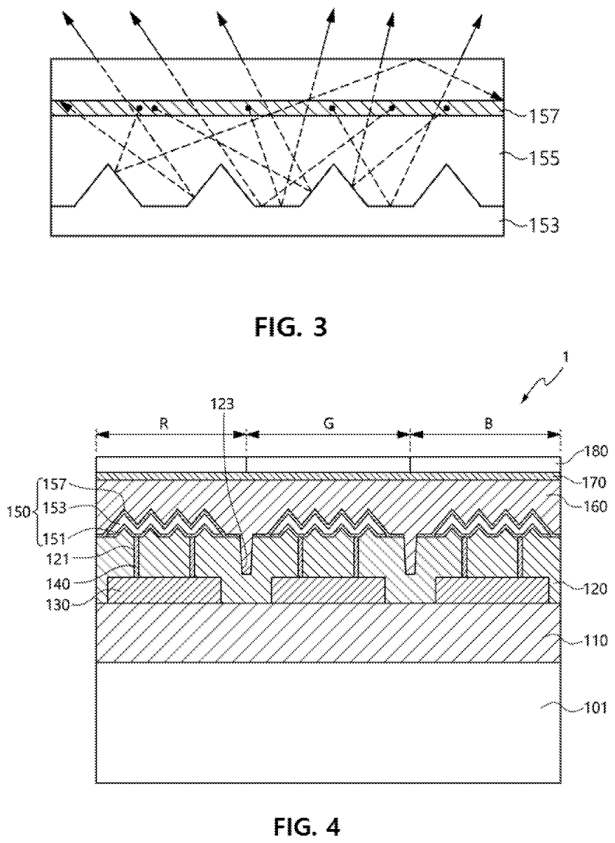

To solve the above problem, referring to FIGS. 2 and 3, in the case of the organic light-emitting diode display device 1 according to the present disclosure, an upper surface of the reflective metal 153 includes a non-flat or non-planar portion in each of the pixel regions R, G, and B. In other words, this configuration increases the possibility of lowering the angle of incidence of light striking the reflective metal 153 to be less than or equal to a critical angle. Therefore, there is an advantage of facilitating efficient extraction of light that is reflected repeatedly and that may be lost in the conventional structure to thereby increase the luminous efficiency.

In this case, each of the reflective metal 153, the buffer metal 151 under the reflective metal 153, and the upper insulating film 120 may have the upper surface with a non-flat portion, or only the reflective metal 153 may have the upper surface with a non-flat portion, but there are no limitations thereto.

FIG. 4 is a cross-sectional view illustrating an organic light-emitting diode display device 1 according to one or more other embodiments of the present disclosure.

Referring back to FIG. 2, the dielectric layer 155 is between the reflective metal 153 and the anode metal 157 in each of the pixel regions R, G, and B. In the structure illustrated in FIG. 2, the dielectric layer 155 in each of the pixel regions R, G, and B may vary in vertical thickness (e.g., in consideration of a fine resonance distance). In addition, the dielectric layer 155 may be on the upper surface of the reflective metal 153 so as to cover the entire upper surface of the reflective metal 153 so that the reflective metal 153 is not damaged in a subsequent ashing process or heat treatment process, but there are no limitations thereto. However, the dielectric layer 155 is not present in the device 1 illustrated in FIG. 4. Therefore, the dielectric layer 155 is not an essential element of the present disclosure.

Referring back to FIG. 2 again, the anode metal 157 is on the dielectric layer 155 in each of the pixel regions R, G, and B. One or more transistors on the substrate 101 supply a predetermined voltage to the anode metal 157 in accordance with the voltage on a corresponding data line when a corresponding gate signal is input from a corresponding gate line. The anode metal 157 may be substantially flat or planar in a lateral direction on the dielectric layer 155 as illustrated in FIG. 2, or may be on the reflective metal 153 in a shape conforming to the reflective metal 153 as illustrated in FIG. 4, but there are no limitations thereto. In the latter case, the reflective metal 153 may also include at least two arbitrary points of different heights in each of the pixel regions R, G, and B.

Hereinafter, a description will be given of the structure and problems of a conventional organic light-emitting diode display 9.

Referring to FIG. 1, in the structure of the conventional organic light-emitting diode display device 9, the anode 950 covers only an upper surface of the dielectric layer 930. Therefore, lateral sides (e.g., side walls) of the reflective electrode 910 under the dielectric layer 930 are inevitably exposed during subsequent processing. Here, when a subsequent ashing process or heat treatment process is performed with the lateral sides of the reflective electrode 910 exposed, the reflective electrode 910 may be damaged because it is made of or includes silver and/or aluminum, which may have a relatively low melting point. Such damage may cause a decrease in reflectivity of the reflective electrode 910 and may result in a leakage path between adjacent pixel regions R, G, and B.

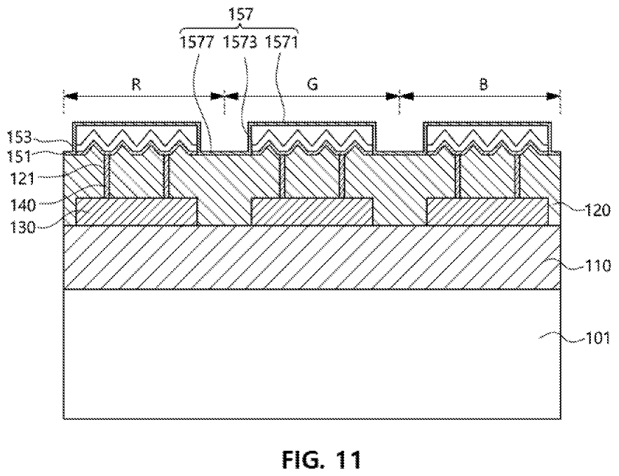

In order to solve the above problems, referring to FIGS. 2 and 4, the anode metal 157 of the organic light-emitting diode display device 1 extends downwards a predetermined distance (e.g., to the uppermost surface of the upper insulating film 120) to cover lateral sides of the reflective metal 153, and when present, the dielectric layer 155. For example, the anode metal 157 may include a first extended portion 1571 (FIG. 11) covering an upper surface of the dielectric layer 155 and a second extended portion 1573 covering each lateral side of the reflective metal 153 and the dielectric layer 155. The second extended portion 1573 may be connected to each lateral end of the first extended portion 1571, but there are no limitations thereto.

The anode metal 157 may further include a third extended portion 1575 extending from the second extended portion 1571 to the trench and/or hole 123 in the upper insulating film 120. The third extended portion 1575 can be removed by a separate process after the anode metal 157 is formed, but it is not necessary to do so when the trench 123 is formed. In any case, the third extended portion 1575 is not an essential element of the present disclosure. In addition, the third extended portion 1575 ensures that the lateral side of the reflective metal 153 (and optionally the buffer metal 151, when present) is more reliably covered.

An organic light-emitting layer 160 is on the upper insulating film 120 and the lower electrode structure 150. The organic light-emitting layer 160 may include a hole transport layer (HTL), a hole injection layer (HIL), an emitting layer (EML), an electron transport layer (ETL), and an electron injection layer (EIL). When a voltage is applied to the anode metal 157 and a cathode metal 170 (described later), holes and electrons move toward the organic light-emitting layer 160 and recombine to emit light. The organic light-emitting layer 160 may be a common layer that is shared by the pixel regions R, G, and B.

The cathode metal 170 may be on the organic light-emitting layer 160. A color filter layer 180 may be on the cathode metal 170. The cathode metal 170 may be a common layer that is shared by the pixel regions R, G, and B.

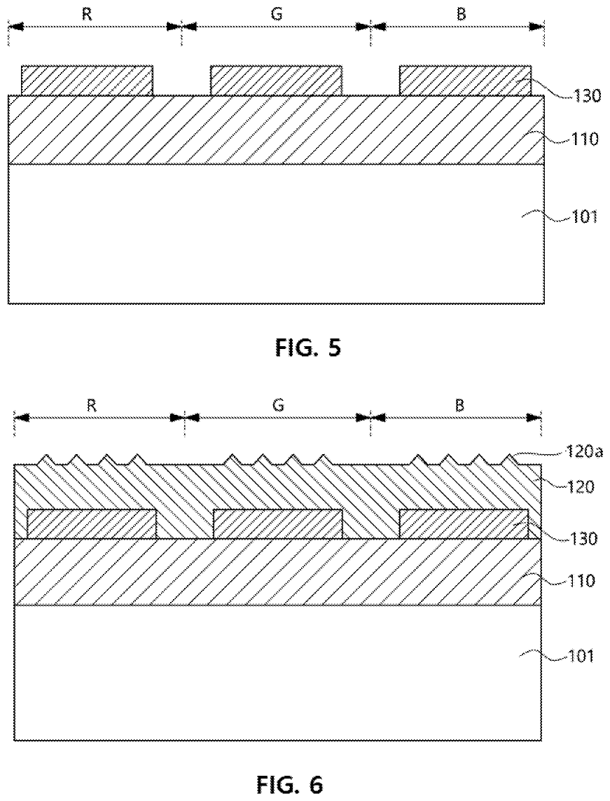

FIGS. 5 to 13 are reference views illustrating a method of manufacturing an organic light-emitting diode display device 1 according to one or more embodiments of the present disclosure.

Hereinafter, the method of manufacturing the organic light-emitting diode display device 1 according to the present disclosure will be described in detail with reference to the accompanying drawings.

First, referring to FIG. 5, a lower insulating film 110 is formed on a substrate 101. Thereafter, a lower metal 130 is formed on the lower insulating film 110. To form the lower metal 130, for example, a metal layer (not illustrated) may be blanket-deposited on the lower insulating film 110, after which a mask pattern having openings in the regions where the lower metal 130 will be removed may be formed on the metal layer, and then the exposed metal layer may be etched to form the lower metal 130 in each pixel region.

Thereafter, referring to FIG. 6, an upper insulating film 120 may be formed on the lower insulating film 110 and the lower metal 130. The upper insulating film 120 may be an inorganic insulator film, for example, a silicon oxide film, a silicon nitride film, or a multilayer film thereof. As described above, the upper insulating film 120 may have a portion in which the height of the uppermost surface is not constant in each of the pixel regions R, G, and B. In other words, the upper insulating film 120 has a non-flat or non-planar portion 120a. To form the non-flat portion 120a, a mask pattern (not illustrated) covering part or all of the non-flat portions 120a and exposing the uppermost surface of the remaining areas of the upper insulating film 120 may be formed on the flat or planar upper insulating film 120 and then etched by a dry etching technique that deposits carbon along the sidewalls of the etched portions of the upper insulating film 120 and forms the sloped surfaces in the upper insulating film 120, or by wet isotropic etching, but there are no limitations thereto other than to form a non-planar uppermost surface in the upper insulating film 120 in each pixel region of the device. Alternatively, the upper surface of the upper insulating film 120 may remain substantially flat by not performing the masking and etching process.

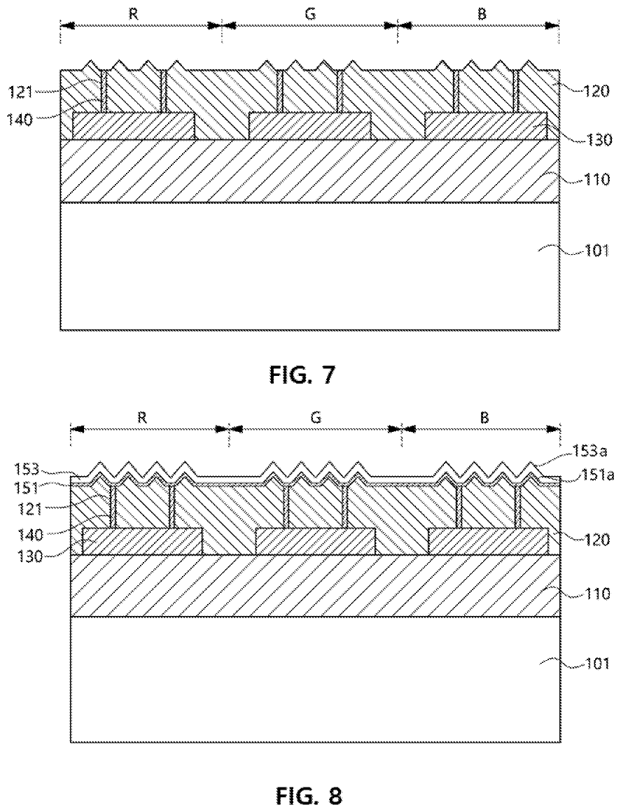

Thereafter, referring to FIG. 7, contacts 140 are formed in the upper insulating film 120. In detail, a mask pattern having openings in the regions where contact holes 121 will be formed is formed on the upper insulating film 120, and then the exposed areas of the upper insulating film 120 are etched to form the contact holes 121 in each pixel region. Then, a metal layer (not illustrated) is deposited on the upper insulating film 120 and in the holes 121 to fill the contact holes 121, and a selective etchback or CMP process (e.g., that selectively removes the metal of the metal layer relative to the insulator of the upper insulating film 120) is performed to expose the upper surface of the upper insulating film 120. The contacts 140 are preferably made of or comprise, for example, a metal such as copper, aluminum, or tungsten, and more preferably, are made of or comprise tungsten.

After the formation of the contacts 140, a lower electrode structure 150 is formed on the upper insulating film 120. First, referring to FIG. 8, a buffer metal 151 is formed on the upper insulating film 120 (e.g., by blanket deposition) and a reflective metal 153 is formed on the buffer metal 151 (e.g., by blanket deposition) in each pixel region. As described above, when the upper insulating film 120 has the non-flat portion 120a, the buffer metal 151 may be deposited on the non-flat portion 120a and naturally have a non-planar portion 151a along the non-flat portion 120a. Alternatively, when the upper insulating film 120 is flat, the buffer metal 151 may be substantially flat.

In addition, the reflective metal 153 may include a non-planar portion 153a along a lateral direction on the non-planar portion 151a and the non-flat portion 120a in each of the pixel regions R, G, and B. In other words, the reflective metal 153 may have at least two arbitrary points of different heights in each of the pixel regions R, G, and B, or one or more points or locations along a lowermost surface that has a height (e.g., a shortest distance from the nearest lower metal structure 130) greater than one or more points or locations along an uppermost surface of the reflective metal 153 in a planar portion thereof. Such a structure may be naturally formed when the buffer metal 151 has the non-planar portion 151a, by forming the reflective metal 153 on the buffer metal 151. Alternatively, when the upper insulating film 120 and the buffer metal 151 are substantially flat, the non-planar portion 153a of the reflective metal 153 may be formed by etching the reflective metal 153 in substantially the same manner as described above for forming the non-flat portions 120a of the upper insulating film 120, but there are no limitations thereto other than as described herein.

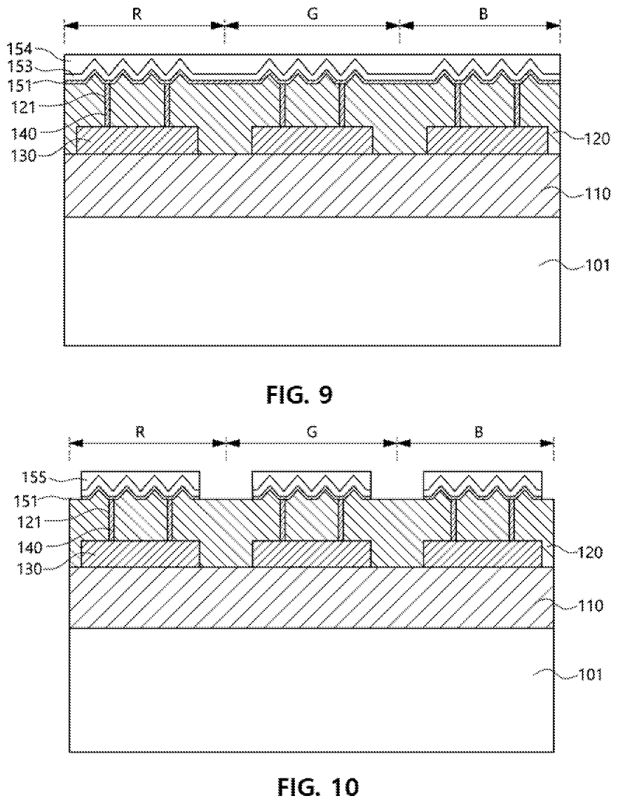

Thereafter, referring to FIG. 9, a dielectric material layer 154 is deposited on the reflective metal 153. Then, referring to FIG. 10, the dielectric material layer 154 is patterned and etched in the boundary region between each of the pixel regions R, G, and B as described herein to form the dielectric layers 155 in each of the pixel regions R, G, and B. In the same process, the reflective metal 153 and the buffer metal 151 may be etched in the boundary region between each of the pixel regions R, G, and B (e.g., using the dielectric layers 155 as a mask).

Thereafter, referring to FIG. 11, an anode metal 157 is formed on the dielectric layer 155 (e.g., by blanket conformal deposition). As described above, the anode metal 157 may cover lateral walls (e.g., side walls) of the reflective metal 153. For example, a metal layer may be deposited on each of the upper insulating film 120, the dielectric layer 155, and lateral walls of the buffer metal 151 and the reflective metal 153. In other words, a first extended portion 1571 and a second extended portion 1573 may be formed on the dielectric layers 155, and a preliminary third extended portion 1577 may be formed on the upper insulating film 120. The formation of the second extended portion 1573 ensures that the entire surface of the reflective metal 153 is not exposed during subsequent processing, thereby protecting the reflective metal 153 during subsequent etching and heat treatment processes. Therefore, it is possible to prevent defects or losses in the reflective metal 153 caused by corrosion or precipitation during such processing.

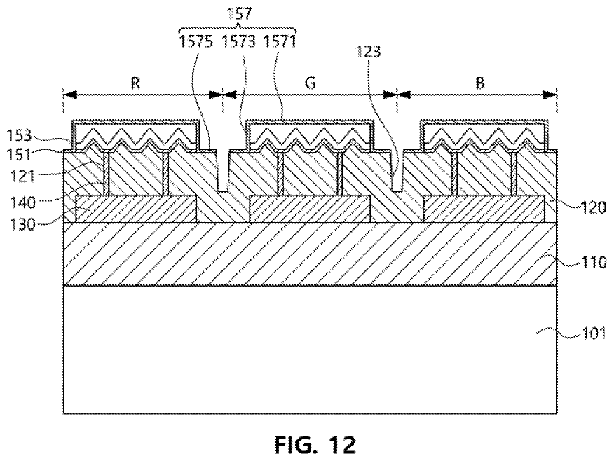

Thereafter, referring to FIG. 12, a patterning and etching process for forming trenches and/or holes 123 in the upper insulating film 120 is performed. The anode metal 157 is also patterned and etched in the region where the trenches and/or holes 123 are formed. In detail, a mask pattern having openings in the regions where the trenches and/or holes 123 will be formed is formed on the anode metal 157, and then the anode metal 157 and the upper insulating film 120 are etched to form the trenches and/or holes 123 at the boundaries between adjacent pixel regions. As a result, the preliminary third extended portion 1577 is partially etched to form the third extended portions 1575. As described above, since the third extended portions 1575 and the trenches and/or holes 123 are formed simultaneously by the same process, a separate process is not required.

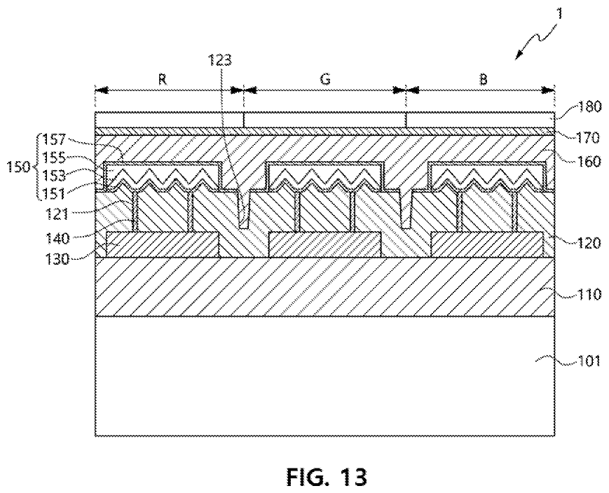

Thereafter, referring to FIG. 13, an organic light-emitting layer 160 is formed on the lower electrode structures 150 and in the trenches and/or holes 123, after which a cathode metal 170 is formed on the organic light-emitting layer 160. Thereafter, a color filter layer 180 is formed on the cathode metal 170 (e.g., by conventional processing).

The foregoing detailed description merely sets forth examples of the disclosure. Also, the above contents explain various embodiments of the present disclosure, and the present disclosure may allow various combinations, modifications, and environments. In other words, the present disclosure may be changed or modified within the scope of the concept of disclosure disclosed herein, the disclosed contents, their equivalents and/or the techniques and knowledge in the art. The foregoing embodiments are for illustrating the best mode for implementing the technical idea of the present disclosure, and various modifications may be made therein according to specific application fields and uses of the present disclosure. Therefore, it is intended that the scope of the present disclosure be defined by the appended claims and their equivalents.

What is claimed is:

1. An organic light-emitting diode display device comprising:
a substrate;
a lower insulating film on the substrate;
a lower metal on the lower insulating film;
an upper insulating film on the lower insulating film and surrounding the lower metal; and
a lower electrode structure on the upper insulating film,
wherein the lower electrode structure comprises a reflective metal configured to reflect light incident on the upper insulating film, and
the reflective metal has a non-flat portion in each pixel region.

2. The organic light-emitting diode display device of claim 1, wherein the reflective metal has a portion having tangential angles at two arbitrary points in each pixel region that are different from each other.

3. The organic light-emitting diode display device of claim 1, wherein the reflective metal has at least two arbitrary points of different heights in each pixel region.

4. The organic light-emitting diode display device of claim 1, wherein the lower electrode structure further comprises:
a dielectric layer on the reflective metal; and
an anode metal on the dielectric layer.

5. The organic light-emitting diode display device of claim 1, wherein the upper insulating film has a non-flat portion in each pixel region, and
the reflective metal has (i) a lower surface of on the non-flat portion of the upper insulating film and (ii) a shape conforming to the non-flat portion of the upper insulating film.

6. An organic light-emitting diode display device comprising:
a substrate;
a lower insulating film on the substrate;
a lower metal on the lower insulating film;
an upper insulating film on the lower insulating film and surrounding the lower metal; and
a lower electrode structure on the upper insulating film,
wherein the lower electrode structure comprises:
a reflective metal configured to reflect light incident on the upper insulating film; and
an anode metal on the reflective metal,
the reflective metal has a non-flat portion in each pixel region, and
the anode metal covers lateral walls of the reflective metal.

7. The organic light-emitting diode display device of claim 6, wherein the lower electrode structure further comprises a dielectric layer between the reflective metal and the anode metal,
the dielectric layer covers lateral walls of the reflective metal, and
the anode metal entirely covers side walls of the dielectric layer.

8. The organic light-emitting diode display device of claim 6, wherein the anode metal has a shape conforming to the reflective metal.

9. The organic light-emitting diode display device of claim 6, wherein the lower electrode structure further comprises a buffer metal between the upper insulating film and the reflective metal.

10. The organic light-emitting diode display device of claim 9, wherein each of the upper insulating film and the buffer metal has a non-flat portion in each pixel region.

11. The organic light-emitting diode display device of claim 6, wherein the upper insulating film comprises a trench and/or hole at a boundary between adjacent pixel regions.

12. A method of manufacturing an organic light-emitting diode display device, the method comprising:
forming a lower insulating film on a substrate;
forming a lower metal on the lower insulating film;
forming an upper insulating film on the lower metal and the lower insulating film; and
forming a lower electrode structure on the upper insulating film,
wherein forming the lower electrode structure comprises forming a reflective metal on the lower insulating film so as to have at least two points of different heights in each pixel region.

13. The method of claim 12, wherein forming the upper insulating film comprises:
depositing the upper insulating film on the lower insulating film; and
forming a non-flat portion in the upper insulating film by partially etching an upper surface of the upper insulating film in each pixel region.

14. The method of claim 13, wherein the reflective metal is on the upper insulating film in each pixel region and has a substantially uniform thickness.

15. The method of claim 12, wherein forming the lower electrode structure further comprises:
forming a dielectric layer on the reflective metal; and
forming an anode metal on the dielectric layer, and
the dielectric layer entirely covers exposed sides of the reflective metal.

16. The method of claim 12, wherein forming the lower electrode structure further comprises forming an anode metal on the reflective metal, the anode metal having a shape corresponding to the reflective metal.

17. A method of manufacturing an organic light-emitting diode display device, the method comprising:
forming a lower insulating film on a substrate;
forming a lower metal on the lower insulating film;
forming an upper insulating film on the lower metal and the lower insulating film; and
forming a lower electrode structure on the upper insulating film,
wherein forming the lower electrode structure comprises:
forming a reflective metal on the lower insulating film so as to have at least two points of different heights in each pixel region;
forming a dielectric layer on the reflective metal; and
forming an anode metal on the reflective metal, and
the anode metal entirely covers exposed sides of the dielectric layer and the reflective metal.

18. The method of claim 17, wherein forming the lower electrode structure further comprises forming a buffer metal on the upper insulating film, before forming the reflective metal.
